(19) United States
(12) Patent Application Publication
(10) Pub. No.: US 2023/0360896 A1
(43) Pub. Date: Nov. 9, 2023

(54) AUTONOMOUS FREQUENCY RETRIEVAL FROM PLASMA POWER SOURCES

(71) Applicant: Applied Materials, Inc., Santa Clara, CA (US)

(72) Inventors: David Coumou, Webster, NY (US); Valeriy Serebryanskiy, Santa Clara, CA (US)

(21) Appl. No.: 17/737,665

(22) Filed: May 5, 2022

(51) Int. Cl. H01J 37/32; G01R 23/02

(52) U.S. Cl. CPC H01J 37/32935; H01J 37/32183; G01R 23/02; H01J 2237/24564; H01J 2237/332; H03L 7/06

(57) ABSTRACT

Embodiments disclosed herein include a processing tool. In an embodiment the processing tool comprises a transmission line sensor, and an analog to digital (A/D) converter. In an embodiment, the processing tool may further comprise a digital down converter (DDC), and a frequency digital phase lock loop (dPLL). In an embodiment, the processing tool may further comprise a transmission line scaling module.

### BACKGROUND

### 1) Field

Embodiments relate to the field of semiconductor manufacturing and, in particular, to a semiconductor processing tool that is configured to provide frequency retrieval from plasma power sources.

### 2) Description of Related Art

In plasma processing tools, the plasma is ignited by a cathode that is coupled to processing gasses within a chamber. In most tools, a power supply is coupled to the cathode through an impedance matching network (sometimes referred to simply as a “match”). The match allows for the impedance of the system to be adjusted in order to match the impedance of the load to which the cathode is coupled. The load has a wide range of impedances that are dictated by parameters such as processing conditions, chamber architecture, and the like. Matching the impedances is important in order to provide efficient power transfer from the power supply to the load.

In addition to matching impedances, it is also important to know the precise frequency of the power being supplied by the power supply. Accordingly, frequency detection systems may be included in the power delivery network. Currently existing schemes for frequency identification require messaging or other information passing from different systems or subsystems in order to determine the frequency. Optimal messaging and/or information passing requires a point-to-point network connection and is subject to large group delays between actuator control and feedback across various elements of a dynamic system. Accordingly, the necessary frequency feedback is subject to delays.

### SUMMARY

Embodiments disclosed herein include a processing tool. In an embodiment the processing tool comprises a transmission line sensor, and an analog to digital (A/D) converter. In an embodiment, the processing tool may further comprise a digital down converter (DDC), and a frequency digital phase lock loop (dPLL). In an embodiment, the processing tool may further comprise a transmission line scaling module.

Additional embodiments disclosed herein may also include a processing tool. In an embodiment, the processing tool comprises a transmission line sensor, and an analog to digital (A/D) converter. In an embodiment, the processing tool may further comprise a digital down converter (DDC), and a transmission line scaling module.

Additional embodiments may include a semiconductor processing tool. In an embodiment, the semiconductor processing tool may include a chamber, a plasma source coupled to the chamber, and a signal processing module for determining a frequency of a plasma generated by the plasma source. In an embodiment, the signal processing module comprises a transmission line sensor, an analog to digital (A/D) converter, a digital down converter (DDC), a frequency digital phase lock loop (dPLL), and a transmission line scaling module.

### BRIEF DESCRIPTION OF THE DRAWINGS

FIG. 1 is a schematic of a plasma processing tool that includes a centralized control architecture, in accordance with an embodiment.

FIG. 2 is a plan view illustration of a sensor with a current loop, a voltage ring, and a guard ring, in accordance with an embodiment.

FIG. 3 is a pair of graphs that illustrate the down converting that results in a low pass filter that extracts the desired signal(s) while attenuating other signals, in accordance with an embodiment.

FIG. 4 is a process flow diagram that depicts a process for determining a frequency of a power supply with a process power control module, in accordance with an embodiment.

FIG. 5 is a schematic of a processing system used to identify the frequency of the signal, in accordance with an embodiment.

FIG. 6 is a schematic illustration of a signal processing module when there is no interference, in accordance with an embodiment.

FIG. 7 is a schematic of the signal processing architecture, in accordance with an embodiment.

FIG. 8 illustrates a block diagram of an exemplary computer system that may be used in conjunction with a processing tool, in accordance with an embodiment.

### DETAILED DESCRIPTION

Systems described herein include a power delivery architecture configured to provide frequency retrieval from plasma power sources. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, for real-time process control and monitoring, the knowledge of the frequency of the process power is important. Accordingly, embodiments disclosed herein include a detection and retrieval process with high accuracy, minimal group delay, and optimal control. Additionally, the scheme described herein is autonomous and does not require messaging and/or information passing from other systems or subsystems.

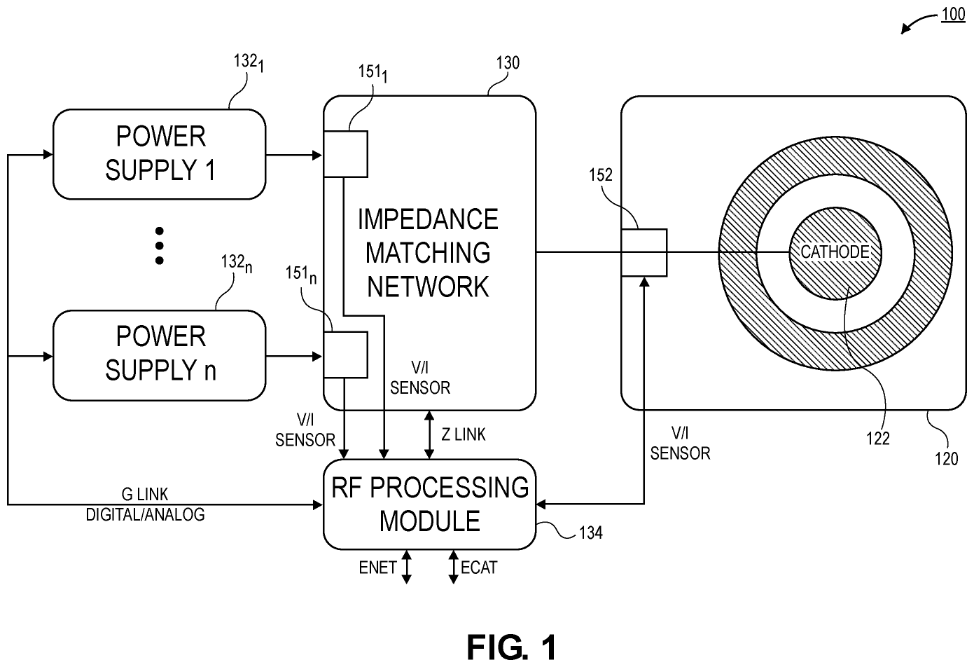

Referring now to FIG. 1, a more detailed schematic of a plasma processing tool 100 is shown, in accordance with an embodiment. In an embodiment, the plasma processing tool 100 includes a plasma chamber 120. The plasma chamber 120 includes a cathode 122 in order to couple the power received to one or more gasses flown into the plasma chamber 120. In an embodiment, the plasma chamber 120 may be suitable for any plasma process typical of semiconductor manufacturing environments. For example, the plasma chamber 120 may be a plasma etching chamber, a plasma deposition chamber, a plasma treatment chamber, or the like. In a particular embodiment, the plasma chamber 120 may be a plasma enhanced chemical vapor deposition (PECVD) chamber, a physical vapor deposition (PVD) chamber, or a plasma enhanced atomic layer deposition (PEALD) chamber.

In an embodiment, the plasma chamber 120 may be coupled to a power delivery architecture. For example, the power delivery architecture may include one or more power supplies 132₁-132ₙ. In the illustrated embodiment, a plurality of power supplies 132 are shown. However, it is to be appreciated that a single power supply 132 may be used in some embodiments. In an embodiment, the power supplies 132 may include any type of power supply. For example, the power supplies 132 may be RF power supplies, microwave power supplies, direct current (DC) power supplies, pulsed DC power supplies, or the like.

In an embodiment, the power supplies 132 may be coupled to the cathode 122 through an impedance matching network 130. The impedance matching network 130 alters the impedance of the power delivery architecture in order to match the load in the chamber 120. Due to changes in processing conditions (e.g. gas flow rates, pressure, temperature, etc.) the impedance of the load can vary. As such, the impedance matching network 130 is used to match the changing impedance in order to provide efficient power delivery into the chamber (i.e., with no or minimal reflected power).

In an embodiment, sensors 151 and 152 may be provided on opposite ends of the impedance matching network 130. For example, sensors 151₁-151ₙ may be on an upstream side of the impedance matching network 130, and sensor 152 may be on a downstream side of the impedance matching network 130. The “upstream” side may refer to the input side of the matching network 130, and the “downstream” side may refer to the output side of the matching network 130. As shown, a plurality of sensors 151₁-151ₙ are provided on the upstream side of the impedance matching network 130. The number of sensors 151 may be equal to the number of power supplies 132. That is, each power supply 132 may have a dedicated sensor 151. The downstream side of the impedance matching network 130 may have a single sensor 152. However, it is to be appreciated that when there is more than one output from the matching network 130, there may be additional sensors 152. For example, in a case where there is two outputs (e.g., for a center of the chamber 120 and an edge of the chamber 120), there may be two sensors 152.

In the case of multiple sensors 151, the plurality of sensors 151₁-n may be fabricated on a single PCB. That is, a single module may include multiple sensors. Generally, embodiments described herein include electrical shielding techniques that limit the cross coupling between sensors on a single PCB.

In FIG. 1, the sensors 151 and 152 are shown generally as blocks. However, it is to be appreciated that the sensors 151 and 152 may be similar to any of the sensor architectures described in greater detail below. For example, each sensor 151 and/or 152 may be a voltage and current (i.e., V/I) sensor. The voltage may be detected by an embedded voltage ring, and the current may be detected by a current loop. The sensors may have an aperture through which a cable (e.g., an RF cable) passes.

In an embodiment, the sensors 151 and 152 may be communicatively coupled with a process power control module 134. For example, an RF process power control module 134 may be provided in FIG. 1. However, it is to be appreciated that the processing module may be a microwave process power control module 134, a DC process power control module 134, or the like, depending on what type of power supplies 132 are included in the tool 100. In an embodiment, the sensors 151 and 152 deliver the voltage and/or current to the process power control module. In an embodiment, the process power control module may have external connections, such as an ENET and an ECAT connection.

In an embodiment, the process power control module 134 may be coupled to the impedance matching network by a digital/analog link. Through the digital/analog link, the process power control module 134 may be able to send control signals to the impedance matching network 130. For example, control signals may be used to adjust the capacitance of variable capacitors within the impedance matching network 130. Additionally, the process power control module 134 may be coupled to the power supplies 132 by a digital/analog link. As such, the process power control module 134 is capable of coordinated impedance tuning.

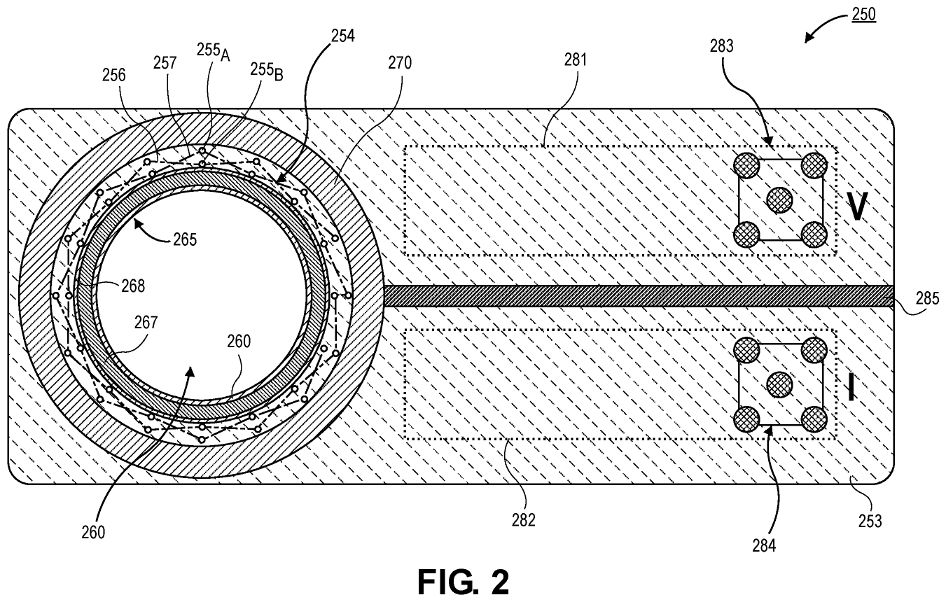

Referring now to FIG. 2, a plan view illustration of sensor 250 is shown, in accordance with an embodiment. As shown, the sensor 250 is fabricated on a PCB 253. The sensor 250 may include a current loop 254 and a voltage ring 265 within the current loop 254. The current loop 254 and the voltage ring 265 may surround an aperture 260 through the PCB 253.

In an embodiment, the current loop 254 may include inner vias 2558 and outer vias 255A. The vias 255 may be coupled to each other by traces 256 on a top surface of the PCB 253 and by traces 257 on a bottom surface of the PCB 253. In the illustrated embodiment, the current loop 254 includes a pair of windings around the aperture 260.

In an embodiment, the voltage ring 265 may include an inner conductive ring 266 and an outer conductive ring 268. An insulating ring 267 may be provided between the inner ring 266 and the outer ring 268. The inner ring 266 may be the voltage pickup surface and the outer ring 268 may be grounded. In an embodiment, the inner ring 266 may define the outer perimeter of the aperture 260.

In an embodiment, the sensor 250 may further comprise a guard ring 270 that surrounds an outer perimeter of the current loop 254. In an embodiment, the guard ring 270 may be grounded. The guard ring 270 may include vias (not shown) that couple the guard ring 270 to a ring on the bottom side of the PCB 253 with a similar size and shape. As such, an electrically shielding barrier is provided around the pickup components of the sensor 250. Accordingly, sensor performance can be increased.

In an embodiment, the voltage ring 265 may be coupled to pickup circuitry 281 on the PCB 253. The pickup circuitry 281 in FIG. 2 is shown schematically as a dashed box. However, it is to be appreciated that the pickup circuitry 281 may include features, such as filters, amplifiers, and the like. In an embodiment, pads 283 are provided. The pads 283 may be suitable for attaching a connector (not shown) in order to feed voltage information back to a processing module, such as the processing module described in greater detail above.

In an embodiment, the current loop 254 may be coupled to pickup circuitry 282 on the PCB 253. The pickup circuitry 282 in FIG. 2 is shown schematically as a dashed box. However, it is to be appreciated that the pickup circuitry 282 may include features, such as filters, amplifiers, and the like. In an embodiment, pads 284 are provided. The pads 284 may be suitable for attaching a connector (not shown) in order to feed current information back to a processing module, such as the processing module described in greater detail above.

In an embodiment, the pickup circuitry 281 is electrically isolated from the pickup circuitry 282. Electrically isolating the two sets of pickup circuitry 281 and 282 enables a reduction in cross-coupling between the two circuits. As such, performance of the sensor 250 may be improved. In an embodiment, the electrical isolation may be provided by a conductive strip 285 that is provided between the two sets of pickup circuitry 281 and 282. In an embodiment, the conductive strip 285 may be grounded. In some embodiments, the conductive strip 285 is electrically coupled to the guard ring 270. The conductive strip 285 may be provided on a top surface of the PCB 253. In other embodiments, vias may be provided below the strip 285 in order to extend the electrical isolation through a thickness of the PCB 253.

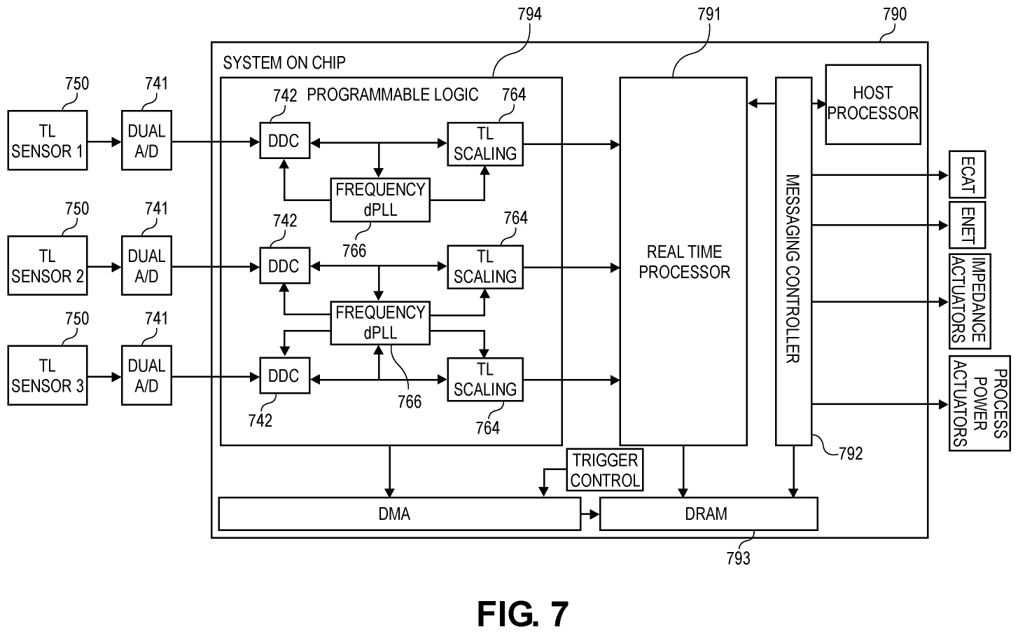

Referring now to FIG. 7, a more detailed illustration of the process power control module 790 is shown, in accordance with an embodiment. As noted above, the process power control module 790 may include functional blocks in order to control the impedance matching network and the one or more power supplies. As noted above, knowing the actual frequency of the power supplies is beneficial for process control. Therefore, embodiments disclosed herein include a process power control module 790 that is configured to implement a frequency detection process.

In an embodiment, the process power control module 790 may include a dual analog-to-digital (A/D) converter 741. The dual A/D converter 741 may receive a first input from a voltage sensor and a second input from a current sensor, such as a transmission line sensor 750. For example, an analog voltage signal and an analog current signal may be provided to the dual A/D converter 741. The analog voltage signal and the analog current signal may be picked up by a sensor such as the sensors described in greater detail above. For example, the sensor may include a current loop and a voltage ring. In an embodiment, the dual A/D converter 741 may have a sample rate of approximately 250 mega samples per second (MSPS) or greater. Though, it is to be appreciated that lower sampling rates are also possible in other embodiments.

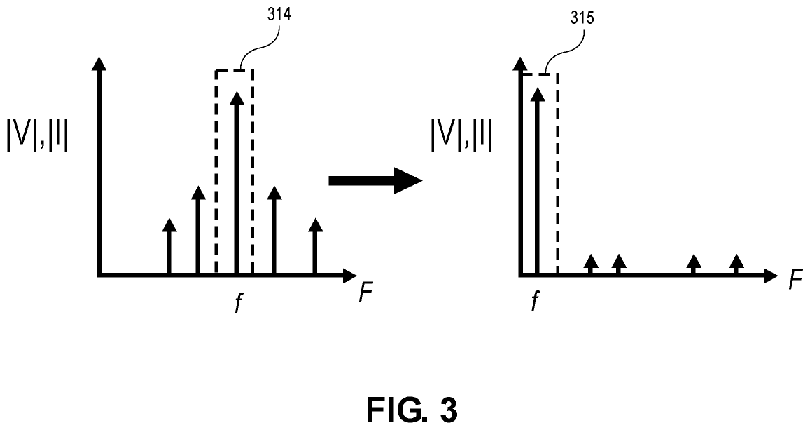

In an embodiment, the converted digital signals can then be processed by a digital down converter (DDC) 742. The digital down converter may take the incoming signals and apply a low pass filter in order to obtain the desired signal. For example, in FIG. 3 the first graph on the left illustrates the incoming digital signal. As can be seen, the desired signal 314 (frequency f) may be surrounded by other signals of various strength. The low pass filter functionality may result in the graph on the right. The graph on the right indicates that the desired signal 315 (frequency f) has been frequency-shifted and passed through the DDC, while the other signals are significantly attenuated. This provides a better signal-to-noise ratio in the system of multiple frequency impairments.

In an embodiment, the output of the digital conversion may be provided in Cartesian coordinates. Additionally, the output may be split into two branches. A first branch may pass directly to a transmission line scaling matrix 764, and the second branch may pass through a digital phase lock loop dPLL 766. The first branch may remain in Cartesian coordinates and propagate a signal at a first rate R. The second branch may start in Cartesian coordinates and propagate a signal at a second rate nR. In an embodiment, the second rate nR may be greater than the first rate R. For example, the second rate nR may be four or more times greater than the first rate R.

In an embodiment, the second branch provides the Cartesian coordinates to a Polar Phase converter block. The frequency can then be fed to the scaling matrix 764 and/or fed back to the DDC 742 in order to provide feedback to the digital down conversion process in order to improve measurement accuracy of the system.

In the description of FIG. 7, a single iteration of the frequency detector is described for simplicity. However, it is to be appreciated that additional frequency detectors may be used in some embodiments. For example, where there are two or more power supplies, there may be a dedicated frequency detector for each of the power supplies. A more thorough explanation of the additional frequency detectors is provided in the further explanation of FIG. 7 provided below.

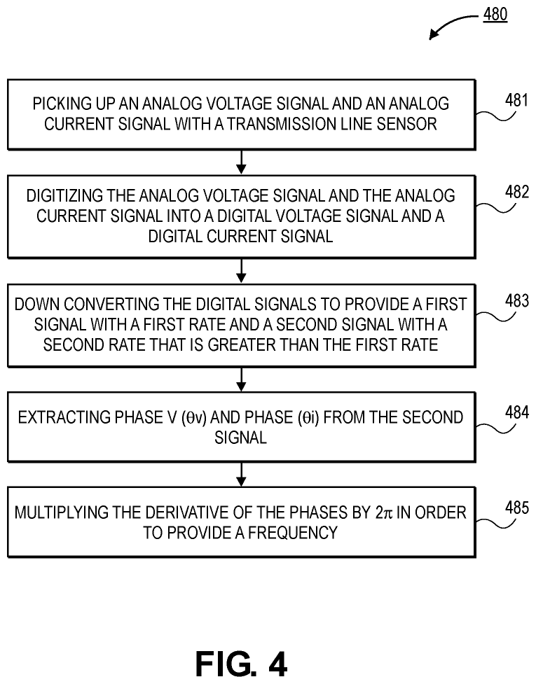

Referring now to FIG. 4, a process 480 for detecting the frequency of a signal from a power source is described in accordance with an embodiment. In an embodiment, the frequency detection may be used as part of a system control architecture in order to provide efficient power delivery from a power source to a load (e.g., a plasma load). In an embodiment, the process 480 may be utilized by a power delivery architecture, such as the architecture described in greater detail above, though similar processes 480 may also be used in other power delivery architectures.

In an embodiment, process 480 may begin with operation 481, which comprises picking up an analog voltage signal and an analog current signal with a transmission line sensor. In an embodiment, the analog voltage signal and the analog current signal may be detected with a sensor that includes a voltage ring and a current loop, such as the embodiments described in greater detail above. In an embodiment, a single sensor may be located before or after an impedance matching network. In other embodiments, multiple sensors may be used (e.g., before and/or after the impedance matching network).

In an embodiment, the process 480 may continue with operation 482, which comprises digitizing the analog voltage signal and the analog current signal into a digital voltage signal and a digital current signal. For example, the digitation process may be implemented by an A/D converter. A dual A/D converter may be used to digitize both signals in some embodiments. In a particular embodiment, the AD converter may have a sample rate of approximately 250 MSPS or greater.

In an embodiment, the process 480 may continue with operation 483, which comprises down converting the digital signals to provide a first signal with a first rate and a second signal with a second rate. In an embodiment, the first rate (i.e., a first signal rate) is less than the second rate (i.e., a second signal rate). In a particular embodiment, the second rate may be approximately four times the first signal rate. In other embodiments, the second rate may be approximately any integer multiple of the first signal rate. The down converting may be implemented with a DDC such as the DDC 342 described in greater detail above.

In an embodiment, the process 480 may continue with operation 484, which comprises extracting phase V (θ_{V}) and phase I (θ_{I}) from the second signal. For example, the second signal may be fed to a frequency detector, such as the one described in greater detail above. In such an embodiment, the desired signal maybe represented in Cartesian form, and is translated to Polar form to derive a time-varying phasor.

In an embodiment, the process 480 may continue with operation 485, which comprises multiplying the derivative of the phases by 2n to convert rotational phase units to revolutions. The multiplication operation may be implemented by a functional block that is configured to do the frequency translation.

In an embodiment, the detected frequency of the desired signal may be fed forward to a scaling matrix. The first signal may also be fed to the scaling matrix. In other embodiments, the detected frequency may optionally be routed back to the DDC as a feedback input in order to improve the accuracy of the frequency detection.

Accordingly, embodiments described herein allow for real-time process control and monitoring that utilizes knowledge of the frequency of the process power. The method of detection and retrieval described herein allow for a high degree of accuracy with minimal group delay, and optimal control. Additionally, the scheme described herein is autonomous and does not require messaging or information passing from other systems or subsystems.

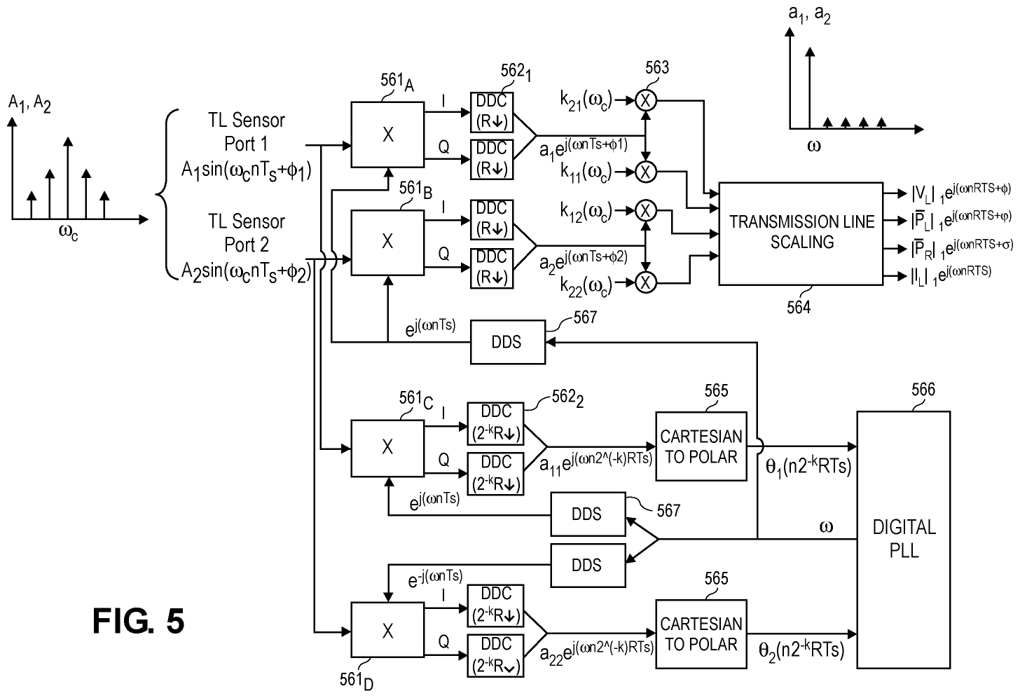

Referring now to FIG. 5, a schematic illustration of the processing system used to identify the frequency of the signal is shown, in accordance with an embodiment. In an embodiment, the graph A₁,A₂ provides an illustration of the incoming signal and interference. The frequency ω_{c} is the frequency of the desired signal and the frequency(s) of the other signals cause interference that impairments the controller's performance and need to be substantially filtered.

In an embodiment, a pair of transmission line sensors (TL sensor port 1 and TL sensor port 2) provide signals into the processing system. The signal from TL sensor port 1 is A₁ sin(ω_{c}nTs+ϕ₁), and the signal from TL sensor port 2 is A₂ sin(ω_{c}nTs+ϕ₂). The signals are routed to dual A/D converters 561_{A} and 561_{B}. The dual A/D converters 561_{A} and 561_{B} are part of a digital down conversion block. Additionally, the signals may be routed to dual A/D converters 561_{C} and 561_{D} which are part of a frequency digital phase lock loop (dPLL) block.

In an embodiment, the dual A/D converters 561_{A} and 561_{B} may each provide an imaginary portion of the signal (Q) and a real portion of the signal (I) to a digital down converter (DDC) 562₁. The DDCs 562₁ may have a sample rate R. The DDCs 562₁ may combine the imaginary Q and real I signals into a complex signal. For example, a first complex signal may take the form of a₁e^{j(ωRTs+ϕ1)} and a second complex signal may take the form of a₂e^{j(ωRTs+ϕ2)}. In an embodiment, scaling factors (e.g., K₂₁, K₁₁, K₁₂, and K₂₂) may then be multiplied against the complex signals at multipliers 563. The results of the multiplication may then be fed to a transmission line scaling module 564. The transmission line scaling module 564 is a linear combination that takes the two complex signals and outputs a set of four outputs. For example, the four outputs may include voltage V_{L}, power forward P_{F}, power reflected P_{R}, and current I_{L}.

In an embodiment, the frequency dPLL block begins with dual A/D converters 561_{C} and 561_{D}. Similar to the dual A/D converters 561_{A} and 561_{B}, the dual A/D converters 561_{C} and 561_{D} provide a real (I) signal and an imaginary signal (Q). The signals I and Q can then be processed by DDCs 5622. The DDCs 5622 may have a sample rate that is different than the sample rate of the DDCs 562₁. For example, the sample rate may be 2⁻¹R in some embodiments. The DDCs output signals that are combined into a complex signal. The complex signals may take the form of a₁₁e^{j(ωn2\hat{ }(-k)RTs)} and a₂₂e^{j(ωn2\hat{ }(-k)RTs)}. In an embodiment, the complex signals may then be converted into a polar form with Cartesian to polar converters 565. The output polar signals may take the form θ₁(n2^{-k}RTs) and θ₂(n2^{-k}RTs). The polar signals may then be processed by a frequency dPLL module 566. The frequency dPLL module 566 may output a frequency ω.

In an embodiment, the output from the frequency dPLL module 566 may be fed to direct digital synthesis (DDS) blocks 567. In an embodiment, the DDS blocks 567 output conjugate modifiers e^{j(ωnTs)} or e^{-j(ωnTs)} that are fed back to the dual A/D converters 561. In the bottom dPLL block, the modifiers may be conjugate pairs. The use of conjugate pairs prevents the dPLL from incorrectly locking to an in-band frequency.

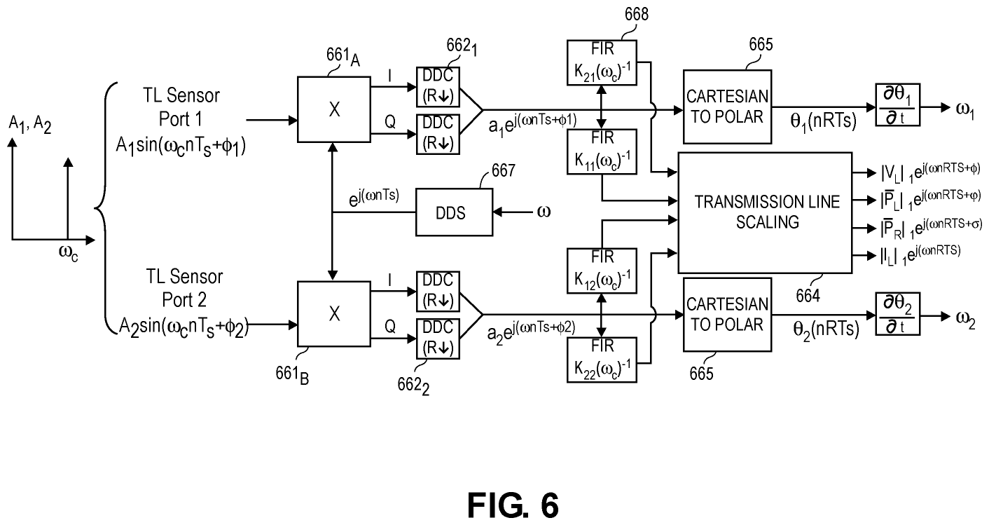

Referring now to FIG. 6, a schematic illustration of a signal processing module when there is no interference is shown, in accordance with an embodiment. As shown in graph A₁,A₂ the only frequency is at ω_{C}. The pair of TL sensors ports may then be fed to dual A/D converters 661_{A} and 661_{B}. The dual A/D converters 661_{A} and 661_{B} may each output a real I and imaginary Q portion of the signal and feed those signals to DDCs 662₁ and 662₂. The DDCs 662 may combine the real and imaginary components of the signal into a complex signal with the forms a₁e^{j(ωRTs+ϕ1)} and a₂e^{j(ωRTs+ϕ2)}

In an embodiment, the complex signals may be converted into a polar form with a Cartesian to polar conversion module 665. The converted signals may have the form θ₁(nRTs) and θ₂(nRTs). The polar form signals may then be used to extract frequency values ω₁ and ω₂. The frequency values may then be fed into a DDS 667 in order to provide an output modifier e^{j(ωnTs)} that is provided to the dual A/D converters 661.

In an embodiment, the complex signals may also be passed through filters 668. The filters 668 may be finite impulse response (FIR) filters. In a particular embodiment, the filters 668 may be equalizing FIR filters. The outputs of the filters 668 may be fed to a transmission line scaling module 664. The transmission line scaling module 664 includes a linear combination that takes the two complex signals and outputs a set of four outputs. For example, the four outputs may include load voltage V_{L}, power forward P_{F}, power reflected P_{R}, and load current I_{L}. Additionally, the scaling matrix may produce direct transfer from raw DDC complex quantities to incident voltage Vᵢ, incident current Iᵢ, reflected voltage Vᵣ, and reflected current Ir.

Referring now to FIG. 7, a schematic of the signal processing architecture is shown, in accordance with an embodiment. In an embodiment, the signal processing architecture may include one or more transmission line sensors 750. For example, three transmission line sensors are shown in FIG. 7. In an embodiment, each transmission line sensor may be coupled to a dual A/D converter 741. The dual A/D converters 741 may be coupled to a system on a chip 790. Particularly, the dual A/D converters are coupled to programmable logic 794 on the system on chip 790. In an embodiment, the programmable logic 794 may include threads for each of the transmission line sensors 750. In an embodiment, each thread may include a DDC 742, a transmission line scaling module 764 and a frequency dPLL 766. In each thread, the DDC 742, the transmission line scaling module 764, and the frequency dPLL 766 may be communicatively coupled to each other, similar to embodiments described in greater detail above.

In some embodiments, the frequency dPLL 766 may be shared between threads. For example, the frequency dPLL 766 for the second transmission line sensor 750 may be shared by the third transmission line sensor 750. That is, a single frequency dPLL 766 may be coupled to a pair of DDCs 742 and a pair of transmission line scaling modules 764.

In an embodiment, the transmission line scaling modules 764 may be communicatively coupled to a real time processor 791. The real time processor 791 may be communicatively coupled to a memory (e.g., DRAM 793) and a messaging controller 792.

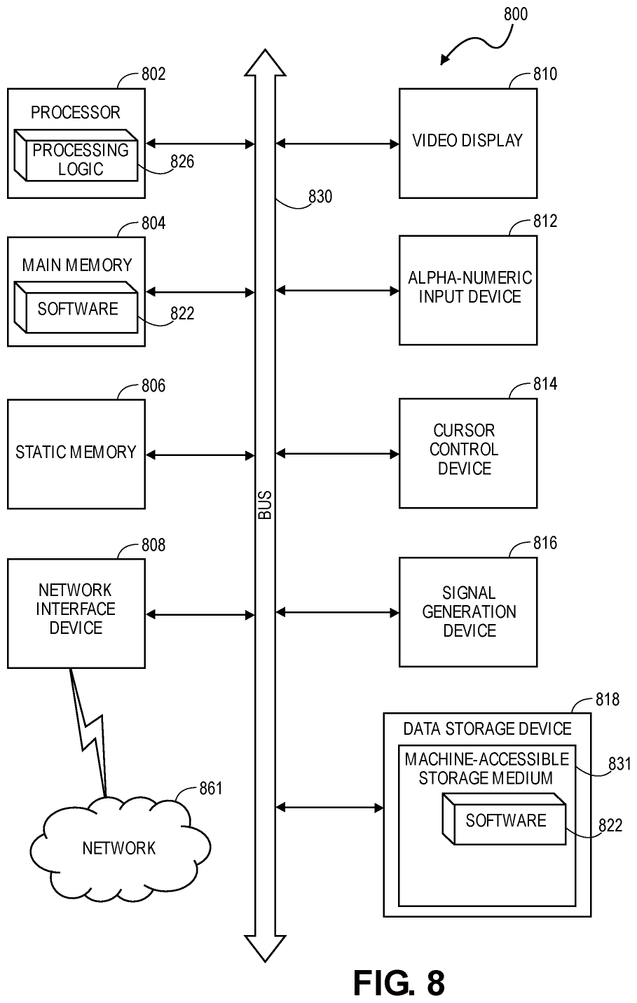

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 832 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 820 via the system network interface device 808. In an embodiment, the network interface device 808 may operate using RF coupling, optical coupling, acoustic coupling, or inductive coupling.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A processing tool, comprising:
a transmission line sensor;
an analog to digital (A/D) converter;
a digital down converter (DDC);
a frequency digital phase lock loop (dPLL); and
a transmission line scaling module.

2. The processing tool of claim 1, wherein the A/D converter is configured to receive analog signals from the transmission line sensor and deliver digital signals to the DDC.

3. The processing tool of claim 2, wherein the frequency dPLL, the transmission line scaling module, and the DDC are communicatively coupled to each other.

4. The processing tool of claim 1, wherein the transmission line sensor comprises a voltage sensor and a current sensor.

5. The processing tool of claim 4, wherein the A/D converter is a dual A/D converter.

6. The processing tool of claim 1, further comprising:
a second transmission line sensor;
a second A/D converter;
a second DDC;
a second transmission line scaling module; and
a second frequency dPLL.

7. The processing tool of claim 6, further comprising:
a third transmission line sensor;
a third A/D converter;
a third DDC; and
a third transmission line scaling module.

8. The processing tool of claim 7, wherein the second frequency dPLL is communicatively coupled to the third DDC and the third transmission line scaling module.

9. The processing tool of claim 1, wherein the DDC is configured to process a real component of a signal from the transmission line sensor and an imaginary component of the signal from the transmission line sensor, and wherein the DDC is configured to combine the real component and the imaginary component into a complex signal.

10. The processing tool of claim 9, wherein the transmission line scaling module includes a plurality of scaling factors, wherein the plurality of scaling factors are each configured to be multiplied by the complex signal.

11. The processing tool of claim 1, wherein the dPLL feeds a frequency back to the DDC through a direct digital synthesis (DDS) module.

12. The processing tool of claim 1, wherein the transmission line scaling module outputs a voltage, a forward power, a reflected power, and a current.

13. The processing tool of claim 1, wherein the dPLL includes a feedback loop, wherein the feedback loop includes multiplying signals by a conjugate pair.

14. A processing tool, comprising:
a transmission line sensor;
an analog to digital (A/D) converter;
a digital down converter (DDC); and
a transmission line scaling module.

15. The processing tool of claim 14, wherein filters are provided before the transmission line scaling module, wherein complex signals pass through the filters.

16. The processing tool of claim 15, wherein the filters are finite impulse response (FIR) filters.

17. The processing tool of claim 14, wherein the transmission line scaling module outputs a voltage, a forward power, a reflected power, and a current.

18. A semiconductor processing tool, comprising:
a chamber;
a plasma source coupled to the chamber; and
a signal processing module for determining a frequency of a plasma generated by the plasma source, comprising:
a transmission line sensor;
an analog to digital (A/D) converter;
a digital down converter (DDC);
a frequency digital phase lock loop (dPLL); and
a transmission line scaling module.

19. The semiconductor processing tool of claim 18, wherein the A/D converter is configured to receives analog signals from the transmission line sensor and deliver digital signals to the DDC.

20. The processing tool of claim 18, wherein the frequency dPLL, the transmission line scaling module, and the DDC are communicatively coupled to each other.
